(19) United States
(12) Patent Application Publication
(10) Pub. No.: US 2008/0107971 A1
(43) Pub. Date: May 8, 2008

(54) Silylphenylene Polymer Composition For The Formation Of Interlayers And Process For The Formation Of Patterns By Using The Same

(75) Inventors: Yasushi Fujii, Kanagawa (JP); Mitsuo Hagihara, Kanagawa (JP); Yoshinori Sakamoto, Kanagawa (JP); Naoki Yamashita, Kanagawa (JP)

Correspondence Address: THELEN REID BROWN RAYSMAN & STEINER LLP, P. O. BOX 640640, SAN JOSE, CA, 95164-0640, US

(73) Assignee: TOKYO OHKA KOGYO CO., LTD., KANAGAWA (JP)

(21) Appl. No.: 11/795,521

(22) PCT Filed: Oct. 25, 2005
(86) PCT No.: PCT/JP05/19585

§ 371 Date: Jul. 17, 2007

(30) Foreign Application Priority Data
Jan. 19, 2005 (JP) 2005-011596

(51) Int. Cl. G03F 1/00

(52) U.S. Cl. 430/5

(57) ABSTRACT

A composition for forming an intermediate layer is provided, having improved etching resistance and prevention of reflection of short-wavelength light (ability to absorb short-wavelength light). The composition for forming an intermediate layer (hard mask) is constituted to include at least (A) a silylphenylene-based polymer having a repeating unit represented by the following general formula (1), and (B) a solvent.

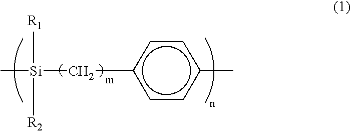

In the formula, R₁ and R₂ are each independently hydrogen or an alkyl group having 1 to 20 carbon atoms; and m and n are integers representing the number of repeating units.

### TECHNICAL FIELD

The present invention relates to a composition for forming an intermediate layer containing a silylphenylene-based polymer and a pattern-forming method using the same. More specifically, the present invention relates to a composition for forming an intermediate layer (hard mask) to be formed between a processed layer and a photoresist layer, the intermediate layer being capable of preventing the reflection of exposing light to be used for patterning the above photoresist layer and having a sufficient difference between the etching rates of the photoresist layer and the processed layer.

### BACKGROUND ART

In the production of an integrated circuit device, the miniaturization of processing size in a lithography process for obtaining an integrated circuit having a high integration density has been progressing. In this lithography process, a photoresist composition is applied to the processed layer, exposed to light, and developed to form a resist pattern, followed by transferring the resist pattern to a processed film, such as a wiring layer or a dielectric layer.

Conventionally, an exposed region of the processed film exposed from the resist pattern is removed by dry-etching. However, a resist layer (hereinafter, also referred to as a “resist pattern”) is thinned corresponding to a shortened wavelength of an exposure light source or the like with the miniaturization of processing size. As a result, it is difficult to fabricate the processed film with a high degree of accuracy because of failure in ensuring a sufficient dry-etching resistance.

Currently, therefore, for transferring the resist pattern to the processed film with a high degree of accuracy, insertion of an intermediate layer (hard mask) between the processed film and the photoresist layer has been considered. For instance, a pattern-forming method that enables patterning with good dimensional controllability was disclosed, including a step of forming an organic silicon film on the processed film, where the organic silicon film has a glass-transition temperature of 0° C. or more and contains an organic silicon compound having a silicon-silicon linkage in its main chain (see, for example, Patent Document 1).

Patent Document 1: Japanese Unexamined Patent Application Publication No. 10-209134 A

### DISCLOSURE OF THE INVENTION

### Problems to be Solved by the Invention

However, various properties such as prevention of reflection of short-wavelength light (ability to absorb short-wavelength light) and etching resistance of the intermediate layer has insufficiently improved, taking into consideration of patterning. Thus, there is a need for a composition for forming an intermediate layer, satisfying these properties simultaneously.

The present invention has been made in consideration of the aforementioned problems, and has as an object to provide a composition for forming an intermediate layer having improved etching resistance and prevention of reflection of short-wavelength light (ability to absorb short-wavelength light).

### Means for Solving the Problems

For solving the above problems, in an attempt to develop a composition for forming an intermediate layer, the present inventors found that superior actions and effects to solve the abovementioned problems can be achieved by using a composition for forming an intermediate layer constituted to include at least (A) a silylphenylene-based polymer having a repeating unit represented by the following general formula (1), and (B) a solvent.

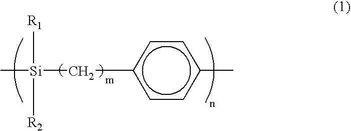

### In the formula, R₁ and R₂ are each independently hydrogen or an alkyl group having 1 to 20 carbon atoms; and m and n are integers representing the number of repeating units.

In other words, the composition for forming an intermediate layer according to the present invention is characterized by containing at least (A) a silylphenylene-based polymer having a repeating unit represented by the following general formula (1), and (B) a solvent.

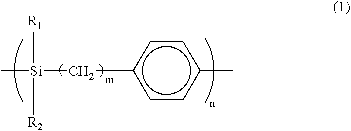

### In the formula, R₁ and R₂ are each independently hydrogen or an alkyl group having 1 to 20 carbon atoms; and m and n are integers representing the number of repeating units.

According to the present invention characterized by the above constitution, a composition for forming an intermediate layer, which enables preventing the reflection of short-wavelength and forming the intermediate layer having a sufficient difference between the etching rates of the photoresist layer and the processed layer, can be provided.

Furthermore, the pattern-forming method of the present invention is characterized by including the steps of: forming an intermediate layer, where the composition for forming an intermediate layer is applied to a processed film to form an intermediate layer; forming a resist pattern, where a resist pattern is formed on the intermediate layer formed in the step of forming the intermediate layer; and etching the intermediate layer, where the intermediate layer is subjected to a dry-etching process using the resist pattern formed in the step of forming the resist pattern as a mask.

### EFFECTS OF THE INVENTION

By using the composition for forming an intermediate layer of the present invention, a pattern with a high degree of dimensional accuracy can be formed. Additionally, the composition for forming an intermediate layer can prevent the reflection of short-wavelength light and have a sufficient difference between the etching rates of the photoresist layer and the processed layer.

### BRIEF DESCRIPTION OF THE DRAWINGS

FIG. 1 shows a graph demonstrating etching rates of the intermediate layer formed from the composition for forming an intermediate layer of the present invention, and a Th.SiO₂ film.

FIG. 2 shows a graph demonstrating etching rates of the intermediate layer formed from the composition for forming an intermediate layer of the present invention, a Poly-Si film, and a CVD-Si₃O₄ film.

### PREFERRED MODE FOR CARRYING OUT THE INVENTION

Embodiments of the present invention will be described below. The composition for forming an intermediate layer (hard mask) according to the present invention is characterized by containing at least (A) a silylphenylene-based polymer having a repeating unit represented by the following general formula (1), and (B) a solvent.

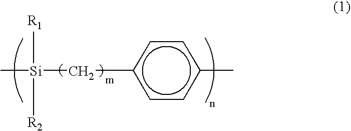

### In the formula, R₁ and R₂ are each independently hydrogen or an alkyl group having 1 to 20 carbon atoms; and m and n are integers representing the number of repeating units.

### [1] Silylphenylene-Based Polymer (A)

The silylphenylene-based polymer (A) used in the present invention is a polymer having a repeating unit represented by the above general formula (1).

R₁ and R₂ are each independently hydrogen or an alkyl group having 1 to 20 carbon atoms. Examples of such alkyl groups include a methyl group, an ethyl group, a propyl group, an isopropyl group, an n-butyl group, a sec-butyl group, a tert-butyl group, a cyclopentyl group, a cyclohexyl group, a 2-ethylhexyl group, an n-octyl group, and the like. Among these, a methyl group and a propyl group are preferred.

R₁ and R₂ in the above general formula (1) are preferably different from each other because the solubility of this polymer (A) in the solvent (B) can be controlled when they are different. A suitable combination of R₁ and R₂ is the combination in which the difference between the numbers of carbon atoms in R₁ and R₂ is two or more. Additionally, at least either one of R₁ and R₂ has preferably ten or less carbon atoms. Specifically, the combination of R₁ and R₂ is preferably, for example, a methyl group and a propyl group, and the like.

The difference between R₁ and R₂ from each other as described above enables the solubility of the polymer (A) in the solvent (B) to be controlled, for example, from 1 to 2% by weight to be approximately 10 to 40% by weight. The solubility of the polymer (A) in the solvent (B) is preferably 0.5 to 50% by weight, more preferably 1 to 20% by weight.

The film thickness of the intermediate layer (hard mask) formed from the above composition for forming the intermediate layer cannot be uniformly limited according to the applications. The lower limit of the film thickness is 10 nm or more, and more preferably 30 nm or more limit, while the upper limit thereof is 1,000 nm or less, preferably 500 nm or less, and more preferably 300 nm or less.

Furthermore, the polymer concentration in the composition for forming an intermediate layer can be adjusted by controlling the solubility of the polymer (A) in the solvent (B) as described above. Thus, this polymer concentration allows for regulation of the film thickness of the intermediate layer (hard mask) to be formed.

The intermediate layer (hard mask) formed from the composition for forming the intermediate layer of the present invention is excellent in antireflection properties since it contains a compound represented by the above general formula (1) having an aromatic ring in its repetitive structure. In particular, it has excellent antireflection properties for rays of light having a short-wavelength of about 193 nm. Furthermore, the backbone of the above general formula (1) is a silylphenylene-based material so that it has excellent etching resistance to etching gas, particularly halogenated gases such as CF₄, C₄F₈, CHF₃, CH₂F₂, or SF₆, compared with an inorganic coating film such as a polysilicon film, an oxide silicon film, or a silicon nitride film. Furthermore, since a resist layer formed on the intermediate layer (hard mask) is an organic layer, it has better etching resistance to the etching gas than the above-mentioned intermediate layer. Furthermore, by adjusting m in the above general formula (1), the ratio of the aromatic ring can be controlled so that the absorbing properties of the intermediate layer (hard mask) formed from the composition for forming the intermediated layer can appropriately be controlled. However, when m in the above general formula (1) is too large, the number of aroma rings is reduced so that absorbance at around 193 nm is diminished. Thus, m is preferably 0 to 20, more preferably 0 to 10, particularly preferably 0.

A preferable silylphenylene-based polymer (A) used in the composition for forming an intermediate layer in the present invention has the number of repeating units represented by n is 1 to 200 in the general formula (1), and the weight average molecular weight thereof is 100 to 10,000, preferably 1,000 to 5,000. This is mainly because the formability and flatness of the film can be easily secured, and etching resistance becomes excellent. Specifically, when the molecular weight of the silylphenylene-based polymer (A) is too low, it volatilizes and thus the film formation may fail. Furthermore, the weight average molecular weight of the polymer (A) can be determined by a method of gel permeation chromatography.

### [2] Solvent (B)

The solvents (B) to be used in the present invention include: monovalent alcohols such as methyl alcohol, ethyl alcohol, propyl alcohol, and butyl alcohol; polyvalent alcohols such as ethylene glycol, diethylene glycol, propylene glycol, glycerin, trimethylolpropane, and hexane triol; monoethers of polyvalent alcohols, such as ethyleneglycol monomethylether, ethyleneglycol monoethylether, ethyleneglycol monopropylether, ethyleneglycol monobutylether, diethyleneglycol monomethylether, diethyleneglycol monoethylether, diethyleneglycol monopropylether, diethyleneglycol monobutylether, propyleneglycol monomethylether, propyleneglycol monopropylether, and propyleneglycol monobutylether; esters such as methyl acetate, ethyl acetate, and butyl acetate; ketones such as acetone, methylethyl ketone, cycloalkyl ketone, and methylisoamyl ketone; polyvalent alcohol ethers prepared by alkyl-etherification of all hydroxyl groups in polyvalent alcohols such as ethyleneglycol dimethylether, ethyleneglycol diethylether, ethyleneglycol dipropylether, ethyleneglycol dibutylether, propyleneglycol dimethylether (PGDM), propyleneglycol diethylether, propyleneglycol dibutylether, diethyleneglycol dimethylether, diethyleneglycol methylethylether, and diethyleneglycol diethylether, and the like. Among them, cycloalkylketone or alkyleneglycol dialkylether are more preferable. In addition, PGDM (propyleneglycol dimethylether) is preferable as an alkyleneglycol dimethylether. These organic solvents may be used alone, or in a combination of two or more. The solvent may be suitably blended in a range of 70% by mass to 99% by mass with respect to the total amount of the composition for forming an intermediate layer.

In the composition for forming an intermediate layer of the present invention, as a polymer other than the silylphenylene-based polymer (A), a low conductive polymer such as polyarylene ether conventionally used in the art can be used in mixture. In this case, the amount of such a polymer mixed should be defined such that the prevention of reflection of short-wavelength light from the composition after mixing may be within a practical range. The rate of etching can be controlled on the basis of the ratio of the conventional low conductive polymer. In addition, a siloxane polymer, for example, a hydrolysate and/or condensate of alkoxysilane, may be mixed.

### [3] Pattern-Forming Method

An example of the pattern-forming method using the composition for forming an intermediate layer of the invention will be given. The pattern-forming method includes at least the following steps (i) to (iii):

(i) A step of forming an intermediate layer, where the composition for forming an intermediate layer of the present invention is applied to a processed film.
(ii) A step of forming a resist pattern, where a resist pattern is formed on the intermediate layer formed by the step of forming the intermediate layer.
(iii) A step of etching the intermediate layer, where the intermediate layer is subjected to a dry-etching process using the resist pattern formed in the step of forming the resist pattern as a mask.

Furthermore, the pattern can be formed on the processed layer in the following step (iv): (iv) a step of etching the processed film, where the processed film is subjected to a dry-etching process using the intermediate layer obtained in the step of etching the intermediate layer as a mask.

Additionally, a step of peeling and removing the resist pattern and the intermediate layer may be provided. Each of the abovementioned steps is described in detail below.

The processed film in the step (i) may be one having a higher etching rate with respect to the halogenated gas, compared with that of the intermediate layer. Examples of the processed film include organic coating films; silicon-based coating films such as a silicon substrate, a polysilicon (Poly-Si) film, a silicon oxide (SiO₂) film, and a silicon nitride (Si₃N₄) film; and inorganic coating films such as metal wiring. These processed films may be formed by any method including a coating method and a CVD method.

The intermediate layer can be formed by applying the composition for forming an intermediate layer on the processed film and then drying by heat process. Furthermore, it may be cured by sintering process after the drying. The coating method used may be any arbitrary method such as a spray method, a spin-coating method, a dip-coating method, or a roll-coating method. The film thickness of the intermediate layer is freely selected depending on the device to which the layer is applied.

The heat process may be carried out, for example, for 1 to 6 minutes at about 80 to 300° C. on a hot plate. In this heat process, the temperature is preferably raised stepwise with three or more steps. Specifically, in an exemplified heat process, a first dry process is carried out for 30 seconds to 2 minutes at about 70 to 120° C. on a hot plate in the air or in an atmosphere of inert gas such as nitrogen; a second drying process is then carried out for about 30 seconds to 2 minutes at about 130 to 220° C.; and subsequently a third drying process is carried out for about 30 seconds to 2 minutes at about 150 to 300° C. In this way, a coating film with a uniform surface can be obtained by carrying out a stepwise drying process including three or more steps, and preferably about three to six steps.

Subsequently, the heat-treated coating film may be subjected to a sintering process. The sintering may be carried out, for example, at a temperature of about 300 to 400° C. in a nitrogen atmosphere. Furthermore, an under layer film may be provided between the processed film and the intermediate layer.

The resist pattern formed in the above step (ii) can be, for example, one formed by applying a photoresist on the intermediate layer and then drying it to form a photoresist layer and subjecting the photoresist layer to light exposure and development. Here, the intermediate layer-formed from the composition for forming an intermediate layer of the present invention has antireflection properties particularly with regard to light at a wavelength of about 193 nm. Using ArF resist as the photoresist, a good resist pattern can be formed. Furthermore, an antireflection film may be provided between the intermediate layer and the photoresist layer. Therefore, even with an exposure light at another wavelength, reflection of the exposure light can be curbed by replacing the above antireflection film with another one, allowing the formation of a good resist pattern. Here, the light exposure and development processes can be carried out using a conventional process in routine lithography.

The etching gas used in the dry-etching process in the step (iii) is, for example, a gas containing a halogenated gas, and the like. The halogenated gas may be one, which can be freely selected for use, which yields a higher etching rate of the intermediate layer than that of the resist pattern. Specifically, such halogenated gas may include, for example, C₄F₈, and CH₂F₂. Thus, using such an etching gas, the intermediate layer can be etched while preventing the resist pattern from corrosion, and transfer of the resist pattern to the intermediate layer is enabled.

The etching gas used in the dry-etching process in the step (iv) is preferably a halogenated gas, for example CF₄, C₄F₈, CHF₃, CH₂F₂, or SF₆. When an intermediate layer formed from the composition for forming an intermediate layer of the present invention is used, the formation of a pattern on an inorganic coating film, particularly a silicon-based coating film, can be easily formed.

### EXAMPLES

Hereinafter, the present invention will be described in more detail by way of Examples of the present invention. However, the present invention is not limited to the following Examples. Except for the chemical agents expressly described, general commercially available chemical agents were used.

### Example 1

### Absorbance, Reflective Index, and Reflectance of 193-nm Wavelength Light

In this Example, a silylphenylene-based polymer (A1) was used, having a molecular weight of 4,000 and having a repeating unit represented by the following chemical formula (2).

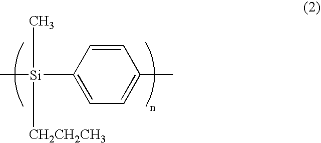

### In the formula, n is an integer representing the number of repeating units.

3% by mass solution of the polymer (A1) in propyleneglycol dimethylether (PGDM), i.e., a composition for forming an intermediate layer was prepared.

The composition for forming an intermediate layer was applied to a silicon wafer by a spin-coating method and then heated on a hot plate for one minute at 80° C. in the atmosphere. Subsequently, the composition was heated at 150° C. for one minute, and further heated at 340° C. for one minute (drying process). The resulting coating film (intermediate layer (hard mask)) had a film thickness of 35 nm.

The absorbance (k) and the reflective index (n) of light at 193 nm were measured using the spectral ellipsometer “WOOLLAM” (manufactured by J.A. WOOLLAM). As a result, the absorbance was 0.666 and the reflective index was 1.518. Subsequently, the reflectance of light was simulated using the absorbance and the reflective index. As a result, the reflectance at a wavelength of 40 nm was 0.82%. From these results, it was confirmed that all of the absorbance, reflective index, and reflectance were excellent.

### Example 2

### Dry-Etching Test

A coating film (intermediate layer (hard mask)) was obtained in a similar manner to Example 1. The resulting intermediate layer was subjected to dry-etching process, and then variations in film thickness before and after the process were measured to determine the etching rates.

The above dry-etching process was carried out as follows:

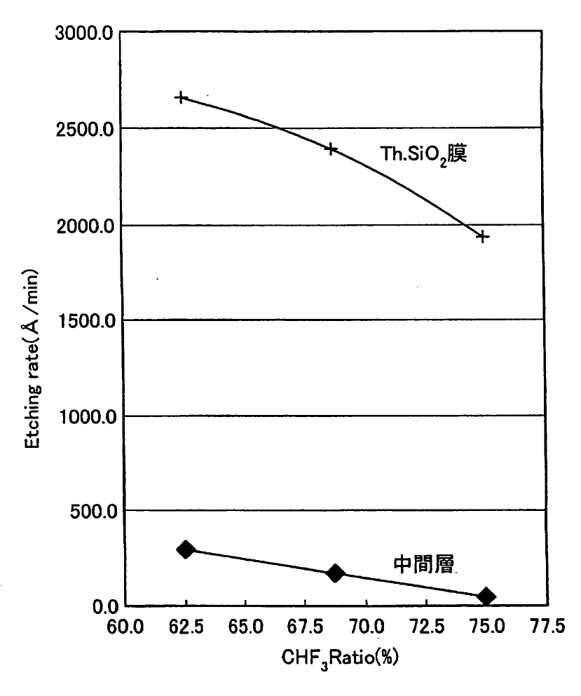

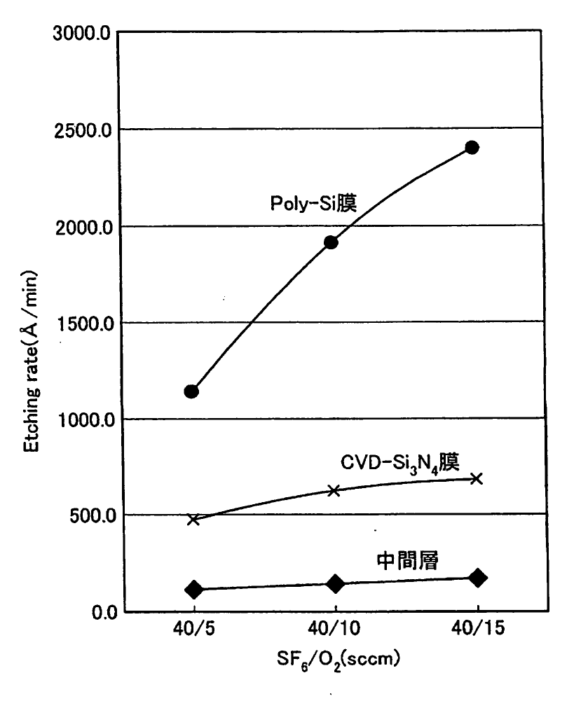

(1) Using an etcher consisting of CF₄/CHF₃/He (flow rate: 120 sccm), dry-etching was carried out with change in the content of CHF₃, on the coating film for 60 seconds under the conditions of a temperature of 20 to 25° C., power of 700 W, and a pressure of 300 mTorr. The results are shown in FIG. 1. FIG. 1 shows a graph demonstrating etching rates of the intermediate layer formed from the composition for forming an intermediate layer of the present invention, and Th.SiO₂ film which is a silicon oxide film formed by thermal oxidation.
(2) Using an etcher consisting of CF₆/O₂ (flow rate: 110 sccm) dry-etching was carried out with change in the ratio of CF₆/O₂, on the coating film for 60 seconds under the conditions of a temperature of 100° C., power of 500 W, and a pressure of 500 mTorr. The results are shown in FIG. 2. FIG. 2 shows a graph demonstrating etching rates of the intermediate layer formed from the composition for forming an intermediate layer of the present invention, a Poly-Si film, and a CVD-Si₃O₄ film which is an Si₃N₄ film formed by a CVD method.

### Comparative Example 1

### Dry-Etching Test

A Th.SiO₂ film was subjected to dry-etching and then the etching rate was determined in a similar manner to (1) in Example 2. The results are shown in FIG. 1.

### Comparative Example 2

### Dry-Etching Test

A Poly-Si film and a CVD-Si₃N₄ film were subjected to dry-etching and then the etching rates were determined in a similar manner to (1) in Example 2. The results are shown in FIG. 2.

From the results of Examples 1 and 2, and Comparative Examples 1 and 2, an intermediate layer formed from the composition for forming an intermediate layer of the present invention was confirmed to have a high etching resistance, compared with that of a Th.SiO₂ film, a Poly-Si film, and a CVD-Si₃N₄ film.

### Example 3

### Evaluation of Pattern Formation

A coating solution (composition for forming an intermediate layer) was obtained in a similar manner to Example 1. The resulting composition for forming an intermediate layer was applied to the Th.SiO₂ film by a spin-coating method and then heated on a hot plate at 80° C. for one minute in the atmosphere. Subsequently, the composition was heated at 150° C. for one minute, and subsequently heated at 320° C. for one minute (drying process). The resulting intermediate film had a film thickness of 35 nm. On the intermediate layer, an acetal-based ArF resist composition was applied by spin-coating, heated at 105° C. for 90 seconds, thereby forming an ArF resist layer having a film thickness of 1200 nm. An exposure process was conducted on the substrate using NSR S-306 (manufactured by Nikon Corporation), and then a development process was carried out for 60 seconds in a 2.38% by weight aqueous TMAH (tetramethylammonium hydroxide) solution to form a resist pattern (resist layer). As a result, an excellent resist pattern was formed.

Subsequently, using an etching gas consisting of CF₆/Ar (flow rate: 10/100 sccm), the intermediate layer was dry-etched under the conditions of a temperature of −10° C., power of 1600/50 W, and a pressure of 3 mTorr, whereby the resist pattern was transferred to the intermediate layer. Consequently, the resist pattern was appropriately transferred to the intermediate layer.

Furthermore, using an etching gas consisting of C₄F₈/CH₂F₂/O₂/Ar (flow rate: 7/31/2/100 sccm), the Th.SiO₂ film provided as a lower layer was etched via the transferred intermediate layer obtained as described above under the conditions of a temperature of 20° C., power of 1600/150 W, and a pressure of 3 mTorr. As a result, an excellent pattern was formed. Finally, patterns of lines and spaces (L/S)=218/58 nm, 238/51 nm, and 230/82 nm could be formed.

### Example 4

### Evaluation of Pattern Formation

In this Example, a silylphenylene-based polymer (A2) was used, having a molecular weight of 1,000 and having a repeating unit represented by the above chemical formula (2).

A 3% by mass solution of 1.0 g of the polymer (A2) in propyleneglycol dimethylether (PGDM) was prepared.

The abovementioned composition for forming an intermediate layer was applied to the Th.SiO₂ film by a spin-coating method and then heated on a hot plate at 80° C. for one minute in the atmosphere.

Then, the composition was heated at 150° C. for one minute, and subsequently heated at 320° C. for one minute (drying process).

A resist pattern was formed in a similar manner to Example 3. Subsequently, the intermediate layer was etched in a similar manner to Example 3. Furthermore, the Th.SiO₂ film provided as a lower layer was etched via the transferred intermediate layer obtained in a similar manner to Example 3. As a result, an excellent pattern was formed at any steps.

### INDUSTRIAL APPLICABILITY

As described above, the composition for forming an intermediate layer of the present invention can be useful for pattern formation using lithography.

1. A composition for forming an intermediate layer formed between a processed film and a resist film comprising at least: (A) a silylphenylene-based polymer having a repeating unit represented by the following general formula (1), and (B) a solvent, 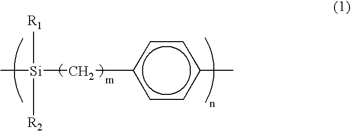
wherein, R₁ and R₂ are each independently hydrogen or an alkyl group having 1 to 20 carbon atoms; and m and n are integers representing the number of repeating units.

2. The composition for forming an intermediate layer according to claim 1, wherein R₁ and R₂ in the above general formula (1) are different from each other.

3. The composition for forming an intermediate layer according to claim 1, wherein the difference between the numbers of carbon atoms in R₁ and R₂ is two or more.

4. The composition for forming an intermediate layer according to claim 1, wherein the silylphenylene-based polymer (A) has a weight average molecular weight of 100 to 10000.

5. The composition for forming an intermediate layer according to claim 1, wherein the exposing light used for the exposure process has a wavelength of 193 nm.

6. The composition for forming an intermediate layer according to claim 1, wherein the solvent (B) is cycloalkylketone or alkyleneglycol dialkylether.

7. A pattern-forming method comprising steps of: forming an intermediate layer, where the composition for forming an intermediate layer according to claim 1 is applied to a processed film to form an intermediate layer; forming a resist pattern, where a resist pattern is formed on the intermediate layer formed in the step of forming the intermediate layer; and etching the intermediate layer, where the intermediate layer is subjected to a dry-etching process using the resist pattern formed in the step of forming the resist pattern as a mask.

8. A pattern-forming method according to claim 7 further comprising a step of etching the processed film, where the processed film is subjected to a dry-etching process using the intermediate layer obtained in the step of etching the intermediate layer as a mask.

9. The pattern-forming method according to claim 8, wherein the dry etching process in the step of etching the processed film uses a halogenated gas as an etching gas.

10. The pattern-forming method according to claim 7, wherein the processed film is an inorganic coating film.
